(19) United States
(12) Patent Application Publication
(10) Pub. No.: US 2022/0395956 A1
(43) Pub. Date: Dec. 15, 2022

(54) METHOD AND APPARATUS FOR IN-SITU MONITORING OF CHEMICAL MECHANICAL PLANARIZATION (CMP) PROCESSES

(71) Applicant: Axus Technology, LLC, Chandler, AZ (US)

(72) Inventors: Daniel Ray Trojan, Chandler, AZ (US); Jessica Brindley, Gilbert, AZ (US)

(21) Appl. No.: 17/838,829

(22) Filed: Jun. 13, 2022

Related U.S. Application Data
(60) Provisional application No. 63/202,533, filed on Jun. 15, 2021.

(51) Int. Cl. B24B 37/013; H01L 21/66

(52) U.S. Cl. CPC B24B 37/013; H01L 22/12

(57) ABSTRACT

A method and an apparatus for in-situ monitoring of chemical mechanical planarization (CMP) processes are disclosed. In one aspect, a CMP system includes a carrier configured to retain a substrate, a platen supporting a polishing pad, an optical detector positioned on a side of the polishing pad opposite the substrate and configured to generate a first signal, one or more position encoders configured to generate second signals, and a controller. The controller is configured to receive the first signal and the second signals, identify one or more measurement sites on the substrate based on the second signals, select one or more of the measurement sites for repeated measurements based on the first signal, and determine the removal rate and/or thickness of a film of the substrate at the selected one or more of the measurement sites based on the first signal and the second signals.

### CROSS-REFERENCE TO RELATED APPLICATION

Any and all applications for which a foreign or domestic priority claim is identified in the Application Data Sheet as filed with the present application are hereby incorporated by reference under 37 CFR 1.57. The present application claims the benefit of priority of U.S. Provisional Patent Application No. 63/202,533, filed Jun. 15, 2021.

### BACKGROUND

### Field

The disclosed technology relates to a method and device for monitoring chemical mechanical planarization (CMP) processes.

### Description of the Related Technology

During chemical mechanical planarization or polishing (CMP), an abrasive and either acidic or alkalinic slurry is applied via a metering pump or mass-flow-control regulator system onto a rotating polishing pad/platen. A substrate or wafer is held by a wafer carrier which is rotated and pressed against a polishing pad on a polishing platen for a specified period of time. The slurry is normally brought to the polishing platen in a single-pass distribution system. The wafer is polished (i.e., planarized) by both mechanical means (e.g., abrasion) and chemical means (e.g., corrosion) during the CMP process.

During the CMP process, the surface of the wafer is removed to provide the planarization or polishing of the wafer. It can be desirable to measure the amount of material removed (e.g., a removal rate and/or thickness of the surface layer) in order to provide an accurate measurement of the effectiveness of the process.

### SUMMARY

One aspect of the disclosed technology is a method comprising: identifying one or more measuring specific site(s) on a wafer in-situ during CMP processing, and correlating measurement data with specific site location(s).

Another aspect is a method for analyzing and characterizing signal quality within the corresponding site location(s) in order to optimize at least one of signal measurement quality, consistency, accuracy, etc.

Yet another aspect is a method of determining one or more location(s) of measurement sites based on at least one measurement criteria, including pre-determined wafer characteristics, random sampling, pre-determined locations of interest, etc., and basing subsequent measurements on the determined criteria and/or analysis of previous sample measurements and locations.

In certain embodiments, a single- and/or multiple-wavelength optical light sources can be used to take the measurement data from the specific site location(s).

In certain embodiments, a non-optical based measurement schemes, such as eddy-current, electrical impedance, etc. can be used to take the measurement data from the specific site location(s).

In certain embodiments, in-platen and/or fixed (external to platen) light sources can be used to take the measurement data from the specific site location(s).

Still yet another aspect is a CMP system comprising a controller configured to implement one or more of the above methods.

Yet another aspect is a chemical mechanical planarization (CMP) system, including a carrier, platen, optical detector, position encoders and a controller. The carrier can be configured to retain a substrate. The platen can be configured to support a polishing pad, wherein the polishing pad includes an opening extending therethrough. The optical detector can be positioned on a side of the polishing pad opposite the substrate, and configured to generate a first signal indicative of a removal rate and/or thickness of a film of the substrate through the opening. The one or more position encoders can be configured to generate second signals indicative of the spatial and angular positions of the carrier and the platen. The controller can be configured to: receive the first signal from the optical detector and the second signals from the one or more position encoders; identify one or more measurement sites on the substrate based on the second signals; select one or more of the measurement sites for repeated measurements based on the first signal; and determine the removal rate and/or thickness of the film of the substrate at the selected one or more of the measurement sites based on the first signal and the second signals.

In certain embodiments, the controller is further configured to determine one or more of the following variables based on the second signals: a first angle between the platen and the selected one or more measurement sites on the substrate, a second angle between the carrier and the selected one or more measurement sites on the substrate, a first radial distance between the platen and the selected one or more measurement sites on the substrate, and a second radial distance between the carrier and the selected one or more measurement sites on the substrate.

In certain embodiments, the controller is further configured to determine a position of each of the selected one or more measurement sites on the substrate with respect to a position of the optical detector.

In certain embodiments, the controller is further configured to determine a timing at which to obtain a sample of the first signal for each of the selected one or more position encoders.

In certain embodiments, the controller is further configured to determine a timing at which to select a measurement from a stream of measurements in the first signal for each of the selected one or more position encoders.

In certain embodiments, the controller is further configured to obtain a plurality of measurements for each of the selected one or more of the measurement sites based on the first signal and the second signals, wherein determining the removal rate and/or thickness of the film of the substrate is further based on the plurality of measurements for each of the selected one or more of the measurement sites.

In certain embodiments, the controller is further configured to determine a suitability of using each of the identified one or more measurement sites for repeated measurement, wherein selecting the one or more of the measurement sites for repeated measurements is further based on the determined suitability.

In certain embodiments, the controller is further configured to obtain a set of predetermined measurement sites, compare a signal quality of the first signals corresponding to the predetermined measurement sites, wherein selecting the one or more of the measurement sites is further based on the signal qualities.

In certain embodiments, the controller is further configured to determine the signal quality of the first signals based on amplitude consistency and/or light spectrum goodness-of-fit.

In certain embodiments, the polishing pad further comprises a window located in the opening and configured to allow light to pass between the optical detector and the substrate.

In certain embodiments, the optical detector comprises an in-situ rate monitor (ISRM) optical detector.

In certain embodiments, the optical detector is embedded within the platen.

In certain embodiments, the platen has an upper surface with an opening formed therein, the opening in the platen overlapping the opening in the polishing pad, and wherein the optical detector is configured to view the substrate via the openings in the platen and the polishing pad.

Yet another aspect includes a method for determining a removal rate and/or thickness of a film on a substrate, comprising receiving a first signal from an optical detector positioned on a side of a polishing pad opposite the substrate, wherein the polishing pad includes an opening extending therethrough; receiving second signals from one or more position encoders, the second signals being indicative of the spatial and angular positions of a carrier and a platen, the carrier configured to retain the substrate and the platen supporting the polishing pad; identifying one or more measurement sites on the substrate based on the second signals; selecting one or more of the measurement sites for repeated measurements based on the first signal; and determining the removal rate and/or thickness of the film of the substrate at the selected one or more of the measurement sites based on the first signal and the second signals.

In certain embodiments, the method further includes determining a position of each of the selected one or more measurement sites on the substrate with respect to a position of the optical detector.

In certain embodiments, the method further includes determining a timing at which to obtain a sample of the first signal for each of the selected one or more position encoders.

In certain embodiments, the method further includes determining a timing at which to select a measurement from a stream of measurements in the first signal for each of the selected one or more position encoders.

In certain embodiments, the method further includes obtaining a plurality of measurements for each of the selected one or more of the measurement sites based on the first signal and the second signals, wherein determining the removal rate and/or thickness of the film of the substrate is further based on the plurality of measurements for each of the selected one or more of the measurement sites.

In yet another aspect a system includes a carrier, a platen, an optical detector, one or more position encoders, and a controller. The carrier can be configured to retain a substrate.. The platen can support a polishing pad comprising a window. The optical detector can be configured to view a film of the substrate via the window and generate a first signal indicative of a removal rate and/or thickness of the film. The one or more position encoders can be configured to generate second signals indicative of the spatial and angular positions of the carrier and the platen. The controller can be configured to receive the first signal from the optical detector and the second signals from the one or more position encoders; identify one or more measurement sites for repeated measurements; and determine the removal rate and/or thickness of the film of the substrate at the one or more of the measurement sites based on the first signal and the second signals.

In some embodiments, the controller is further configured to obtain a set of predetermined measurement sites; and compare a signal quality of the first signals corresponding to the predetermined measurement sites, wherein selecting the one or more of the measurement sites is further based on the signal qualities.

### BRIEF DESCRIPTION OF THE DRAWINGS

The above, as well as additional objects, features and advantages of the disclosed technology, will be better understood through the following illustrative and non-limiting detailed description of certain embodiments of the disclosed technology, with reference to the appended drawings. In the drawings like reference numerals will be used for like elements unless stated otherwise.

FIG. 1 is a schematic illustration of a chemical mechanical planarization system with a process improvement system, showing a wafer carrier holding a wafer in a processing position.

FIG. 2 is a view of the chemical mechanical planarization system of FIG. 1, showing the wafer carrier holding the wafer in a loading position.

FIG. 3 is a schematic illustration of a chemical mechanical planarization system with a process improvement system attached to a movable support structure.

FIG. 4 is a schematic illustration of a chemical mechanical planarization system with a process improvement system embedded in a polishing pad to enable in-situ application of the improvement system process to or on the wafer surface.

FIGS. 5A and 5B are schematic illustrations of a chemical mechanical planarization system with an ISRM optical detector embedded within another component of the system.

FIG. 6 is an illustration of the surface of the polishing pad, a slurry supply, a high pressure rinse device, and a window allowing light from the optical detector to pass through the polishing pad.

FIG. 7 is a schematic illustrations of a measurement point on a wafer with respect to a platen in accordance with aspects of this disclosure.

FIG. 8 shows the surface of a wafer with a deposited film with highly-variable thickness across the wafer, evidenced by the different color fringes indicating different film thicknesses.

FIG. 9 is a flowchart illustrating a method for determining a removal rate and/or thickness of a film on a substrate.

### DETAILED DESCRIPTION

Detailed embodiments of the disclosed technology will now be described with reference to the drawings.

### Introduction to CMP Systems

The adoption and use of chemical mechanical polishing (CMP) for the planarization of thin films in the manufacture of semiconductor Integrated circuits (ICs), MEMS devices, and LEDs, among many other similar applications is common among companies manufacturing “chips” for these types of devices. This adoption includes the manufacture of chips for mobile telephones, tablets and other portable devices, plus desktop and laptop computers. The growth in nanotechnology and micro-machining holds great promise for ever-widespread use and adaptation of digital devices in the medical field, in the automotive field, and in the Internet of Things (the “IoT”). Chemical mechanical polishing for the planarization of thin films was invented and developed in the early 1980s by scientists and engineers at the IBM Corporation. Today, this process is widespread on a global basis and is one of the truly enabling technologies in the manufacture of nearly all digital devices.

Integrated circuits are manufactured with multiple layers and alternating layers of conducting materials (copper, tungsten, aluminium, etc.), insulating layers (silicon dioxide, silicon nitride, etc.), and semiconducting material (polysilicon). A successive combination of these layers is sequentially applied to the wafer surface, but because of the implanted devices on the surface, topographical undulations are built up upon the device structures, as is the case with silicon dioxide insulator layers. These unwanted topographical undulations must be flattened or “planarized” before the next layer can be deposited. In the case of copper layers, the copper is deposited on the surface to fill contact vias and make effective vertical paths for the transfer of electrons from device to device and from layer to layer. This procedure continues with each layer that is applied (usually applied by a deposition process). In the case of multiple layers of conducting material (multiple layers of metal), this could result in numerous polishing procedures (one for each layer of conductor, insulator, and semiconductor material) in order to achieve successful circuitry.

The CMP process is an enabling technology in the manufacture of multi-layer circuitry that makes this all possible. The following describes further details on various components and steps in a non-limiting example of a CMP method and apparatus:

A cost contributor in the CMP process includes the collective costs associated with the consumable set, such as the polishing slurries and the polishing pads. Typical polishing slurries used in CMP processing comprise, for example, colloidal suspensions of abrasive particles (e.g., colloidal silica, colloidal alumina, colloidal ceria, etc.) suspended or contained within, for example, a water-based medium.

The polishing pads are typically polyurethane based. Additionally, the typical CMP polishing pad is usually from 18″ to 24″ in diameter; this dimension is dictated by the size of the polishing platen (i.e., table) on the popular polishing machines in use around the world. However, in some applications (e.g., precision optical applications) they may be even larger in diameter (e.g., up to 48″ or larger). These polishing pads are typically attached to a very flat polishing platen (e.g., polishing table) by pressure sensitive adhesive.

During the CMP process, a slurry is applied, via a metering pump or mass-flow-control regulator or other system, onto a rotating polishing pad. In addition, a substrate or wafer is held by a wafer carrier which is rotated and pressed against the polishing platen for a specified period of time. The term “substrate” and “wafer” are used interchangeably herein, and include, for example, semiconductor or silicon wafers, flat panel displays, glass plates or disks, plastic work-pieces, and other substantially rigid, flat and thin work-pieces of various shapes (e.g., round, square rectangular, etc.) and sizes on which one or more embodiments of the apparatuses and processes disclosed herein can be implemented. Additionally, a slurry may be brought to the polishing platen in, for example, a single-pass distribution system. The normal expectation is that the slurry particles in their media will be distributed evenly between the rotating wafer, and the rotating platen and/or polishing pad. It is quite typical, however, for much of the polishing slurry to not be effective or not be productive because it is swept to the edge of the polishing pad/platen by centrifugal force, and/or by “squeegee” action of the wafer against the polishing pad/platen. Thus, this portion of the polishing slurry may never reach the wafer surface, rendering that portion of slurry an inactive participant in the polishing activity. In some instances, the hydrophobic nature of the surface of the polishing pad contributes to the polishing slurry being swept aside easily and ultimately, swept into a waste drain.

A force is applied to the wafer (e.g., by a substrate carrier head, e.g., via a pressure applied to a membrane within a carrier head) to provide pressure between the wafer and the polishing pad, and thus, press the wafer into the pad for processing. In addition, the wafer and the pad both have motion to create a relative velocity. The motion and force leads to portions of the pad creating abrasion by pushing the abrasive particles or other abrasive against the wafer (i.e., substrate) while it moves across the wafer surface. The corrosive chemicals in the slurry alter the material being polished on the surface of the wafer. This mechanical effect of abrasion combined with chemical alteration is called chemical mechanical planarization or polishing (CMP). Accordingly, the removal rate of material from the substrate can be orders of magnitude higher due to both the chemical and mechanical effects simultaneously compared to either one (chemical or mechanical) taken alone. Similarly, the smoothness of the surface after polishing may also be optimized by using chemical and mechanical effects together.

Yield is the driving force in determining success at the manufacturing level for many products (e.g., integrated circuits, MEMS, LEDs, etc.). Accordingly, the accumulated cost of manufacturing a solid-state device is termed the “Cost-of-Ownership” (CoO) and this term is also applied to each of the required manufacturing steps. Ultimately, the CoO of the CMP process is one of the highest CoO figures in the individual manufacturing steps required to make a semiconductor “chip” and its associated digital device.

Two challenges in the CMP process are the reduction of the amount of polishing slurry needed per layer being polished and increasing the lifetime of the polishing pad and the polishing slurry. Another challenge is to provide accurate monitoring and control of material removal rate, substrate uniformity, layer thickness, and endpoint detection during the CMP process, to increase yield and reduce waste.

For several years, various individuals and innovative companies have attempted to manufacture recycling systems for the polishing slurries. These systems have mostly been either off-line in nature (i.e., away from the polishing room) or in-line in nature (i.e., within the slurry distribution system at Point-of-Use (POU) positioned near each polishing machine). Four important factors to monitor and control for effective CMP polishing slurries are the pH of the slurry, the particle size of the abrasive component, the specific gravity of the slurry, and the cleanliness of the slurry.

As the slurry is distributed onto the polishing pad, environmental factors, such as evaporation, tend to change the fluid media content in the slurry. This change in content tends to affect the pH of the slurry, which, in turn, tends to negatively affect the specific gravity of the slurry. During the polishing process, material (e.g., copper, polysilicon, etc.) is removed from the surface of the wafer that creates microscopic particles. These microscopic particles either remain in suspension in the slurry, become embedded in the polishing pad or some combination of both. These microscopic particles cause scratches on the surface of the film being polished, and thus catastrophic failures in the circuitry.

These physical changes in the make-up of the polishing slurry, while perhaps not disastrous to certain lapping slurries or fine grind slurries in machine shops and precision optical manufacturing applications, can render the surfaces of semiconductor silicon wafers tragically, catastrophically, and/or permanently damaged. These scratches and failures can render a damaged chip useless, and thus negatively affect yield. For these and other reasons, slurry recycling/recirculation systems, while common in metal lapping applications and in some precision optical applications where surface quality tolerances are in microns, have not been particularly successful in the CMP process industry (e.g., within semiconductor fabs) or, for example, in foundries where surface quality tolerances are measured in nanometers and even Angstroms.

It is an object of the disclosed technology to address the many issues described above, with respect to substrate waste, yield and CoO, for example, through the utilization of an in-situ monitoring system in the CMP process to provide increased CMP yields and an overall improvement in the CMP process.

FIG. 1 is a schematic illustration of a chemical mechanical planarization (CMP) system 100 including process improvement system 130 for improving the CMP process. System 100 can include a wafer carrier 150 configured to hold and process a wafer. In the illustrated embodiment, the wafer carrier 150 is in a processing (i.e., lowered) position, holding the wafer or substrate 155 (not shown in FIG. 1) against a polishing pad 110. The polishing pad 110 may be positioned on a supporting surface, such as a surface of a platen 120. In some embodiments, the platen 120 may be configured to raise upward to meet the components of system 100, such as the wafer carrier, the pad conditioning arm, the process improvement system, and the slurry delivery system.

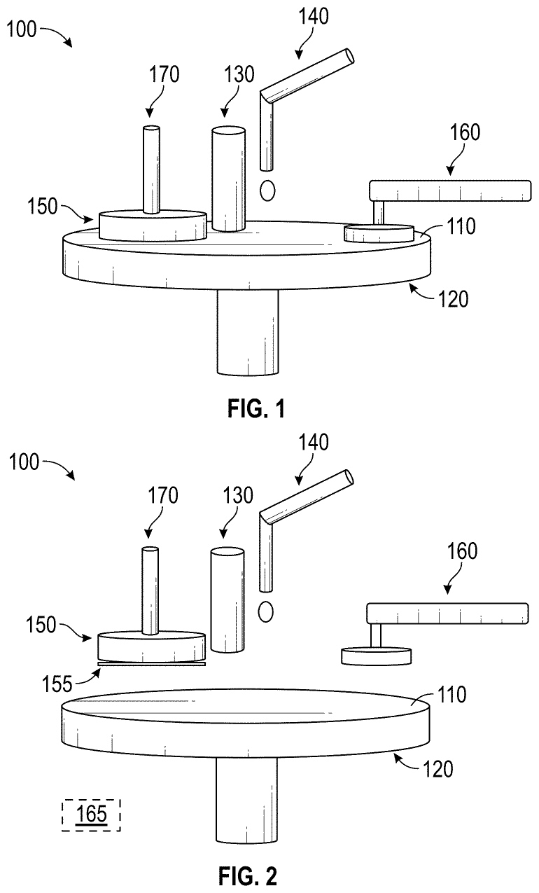

FIG. 2 is a view of the chemical mechanical planarization system of FIG. 1, showing a wafer 155 held by the wafer carrier 150 in a loading (e.g., raised or upper) position. In some embodiments, the wafer 155 can be held, for example, by force of a vacuum. For example, the wafer carrier 150 can hold or attach wafer 155 with a vacuum system, so that the surface of the wafer 155 to be polished faces towards polishing pad 110 when attached to wafer carrier 150. Referring to both FIGS. 1 and 2, system 100 can include a slurry delivery system 140 configured to deliver a processing slurry to the wafer 155 and allow it to be chemically/mechanically planarized against polishing pad 110. System 100 can include a pad conditioning arm 160, which includes a pad conditioner at one end and can be configured to treat or “refresh” the surface roughness (or other processing characteristics of the pad) during or between processing cycles. System 100 can further include a controller 165 which can be configured to provide the functionality of the methods described herein, and additional functionality. In some implementations, the controller 165 may be configured to monitor a removal rate and/or a thickness of the wafer 155 in-situ as described in the “Systems and Methods for In-Situ Measurement of Material Removal and/or Film Thickness” section below. Depending on the embodiment, the controller 165 may include a processor and a memory storing instructions configured to cause the processor to execute the methods described herein. For example, the controller 165 can be configured to communicate (e.g., electronically) with the process improvement systems and/or the mechanical or electro-mechanical apparatus, and/or other CMP equipment components described herein, or other systems or components, to provide functionality thereto.

Referring to system 100 of FIGS. 1 and 2, polishing pad 110 is on the top surface of platen 120 which rotates about an axis. Other orientations and directions of movement can be implemented as a person of ordinary skill in the art would readily appreciate (e.g., counter clockwise about a vertical axis, clockwise, etc.). Platen 120 may be configured to rotate clockwise, counterclockwise, back and forth in a ratcheting motion, etc.

The process improvement system 130 can be mounted stationary relative to, and above the surface of the polishing pad 110, as shown in FIGS. 1 and 2, or can be mounted on a movable support structure, as described further herein. In some embodiments, the process improvement system 130 may be configured to lower such that process improvement system 130 is in closer proximity to the polishing pad 110. In some embodiments, the process improvement system 130 may be configured (e.g., to move or be stationary) such that process improvement system 130 is in closer proximity to the carrier 150. The process improvement system 130 can be oriented or otherwise configured in any way suitable to improve the CMP process described elsewhere herein. The process improvement system can provide process improvements during a wafer polishing process.

In an embodiment, the slurry delivery system 140 can deliver a slurry (e.g., a polishing slurry) to a surface of a polishing pad 110. The polishing slurry may include or contain sub-micron abrasive and corrosive particles. In a non-limiting example, the polishing slurry typically comprises colloidal suspensions of abrasive particles (e.g., colloidal silica, colloidal alumina, colloidal ceria, etc.). In some embodiments, the abrasive particles are suspended in a water-based medium or any other suitable medium. In various embodiments, the slurry delivery system 140 includes a metering pump, a mass-flow-control regulator system, or any other suitable fluid delivery components as a person of ordinary skill in the art would understand.

Accordingly, abrasive particles and corrosive chemicals in the slurry, deposited by the slurry delivery system 140 on the polishing pad 110, mechanically and chemically polish the wafer through abrasion and corrosion, respectively. As shown, the slurry delivery system 140 delivers a slurry that flows downward through the system and ultimately, onto polishing pad 110. In some embodiments, wafer carrier 150 and polishing pad 110 can move relative to each other in any number of different ways, to provide the polishing. For example, wafer carrier 150 can apply a downward force against the platen 120, such that the wafer 155 is pressed against the polishing pad 110, with abrasive particles and corrosive chemicals of the slurry between the wafer 155 and the polishing pad 110 providing chemical and mechanical polishing while polishing pad 110 and wafer carrier 150 move relative to each other. The relative motion between polishing pads and wafer carriers can be configured in various ways, as would be understood by a person of ordinary skill in the art, and either or both can be configured to oscillate, move linearly, and/or rotate, counter clockwise and/or clockwise relative to each other. The movement can be provided through various mechanical or electro-mechanical apparatus, such as motors, linear actuators, robots, encoders, gear boxes, transmissions, etc., and combinations thereof.

Pad conditioning arm 160 conditions the surface of polishing pad 110, by pressing against polishing pad 110 with a force, with relative movement therebetween, such as the relative motion described above with respect to the polishing pad and wafer carrier 155. The pad conditioning arm 160 in the illustrated embodiment can oscillate, with a pad conditioner at one end. In some embodiments, the pad conditioner is configured to rotate clockwise or counterclockwise, for example. In some embodiments, the pad conditioner contacts polishing pad 110 and may make contact as the pad conditioner rotates.

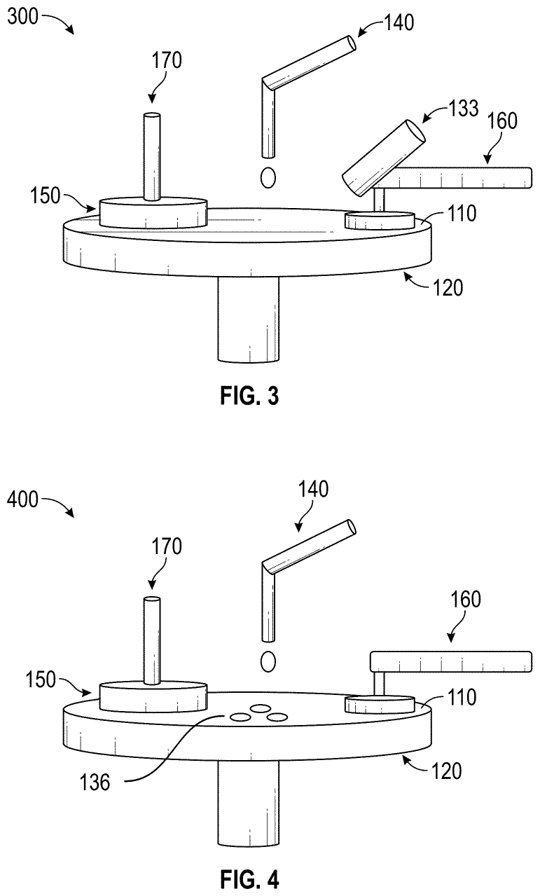

FIG. 3 is a schematic illustration of a chemical mechanical planarization system with a process improvement system 133 attached to a support structure. For example, the support structure may be moveable, such that it can provide variable positioning prior to, after, and/or during polishing. Process improvement system 133 can be mounted either on existing conditioning arms or alternatively, on a separate arm dedicated for positioning independent of the pad conditioner and the pad conditioners sweeping control mechanisms. For example, the process improvement system 133 can be attached to an arm or other support structure, such as pad conditioning arm 160 that moves, for example, or oscillates, to provide such movement functionality. System 300 of FIG. 3 includes polishing pad 110, platen 120, slurry delivery system 140, wafer carrier 150, wafer 155, and pad conditioning arm 160, as described above with respect to FIGS. 1 and 2. However, the system of FIG. 3 differs from the system of FIGS. 1 and 2 in that the process improvement 133 is mounted onto the pad conditioning arm 160, to enable variable positioning of the process improvement system and its interface, for example, with the polishing pad 110 prior to and/or during polishing. In various embodiments, the process improvement system 133 can be mounted on a different support structure, such as a separate arm (not shown), to allow independent positioning of the process improvement system 133 relative to the movement provided by the pad conditioning arm 160. For example, a process improvement system can be positioned and configured to allow it to interface with one or more locations, and/or components of a CMP system. For example, a process improvement system can be configured to interface with a surface of a wafer. A process improvement system can be configured to interface with two or more components of a CMP system, such as a wafer surface and/or a polishing pad surface. In another example, two or more process improvement systems can be implemented within the CMP systems described herein. For example, two process improvement systems may be included for each platen in a system where a system may have multiple platens for CMP processing.

FIG. 4 is a schematic illustration of a chemical mechanical planarization system 400 with one or more detectors 136 (e.g., In-Situ Rate Monitor (ISRM) optics) embedded within another component of the system 400. For example, one or more detectors 136 can be embedded within the platen 120, wafer carrier 150, or within polishing pad 110. In a non-limiting example, the detectors 136 may be implemented as a reflectometer positioned and assembled with respect to the polishing pad 110 to emit light onto the wafer 155 and detect the light reflected from the wafer 155. The light detected by the reflectometer after reflecting from the wafer 155 can be used to detect the removal rate and/or thickness of one or more layer(s) on the wafer 155. Such embodiments can enable in-situ monitoring of the wafer 155 as material is removed. The system of FIG. 4 includes polishing pad 110, platen 120, slurry delivery system 140, wafer carrier 150, wafer 155, and pad conditioning arm 160, as described above with respect to FIGS. 1-3.

Although FIGS. 1-4 illustrate aspects of a CMP apparatus (e.g., wafer carrier 150, wafer 155, a person of ordinary skill of art would understand that CMP machines can be assembled in any number of different ways, for example, without the inclusion of certain components. In addition, FIGS. 1-4 do not necessarily illustrate a complete CMP apparatus (which might otherwise include reference to a wafer carrier head membrane, a body of a CMP apparatus, system for delivering wafer substrates to a particular CMP apparatus, etc.), but is merely meant to be an illustrative example to highlight the disclosed technology that is the subject of this disclosure. A person of ordinary skill in the art would understand that additional components of a CMP system (e.g., membrane, etc.) may be incorporated in the systems described herein. For example, wafer carrier head 150 may further comprise a vacuum system configured to secure a wafer against the membrane using vacuum pressure or suction. The resilient membrane can include one or more separate zones, with compressed gas applied to the top surface or back side of the membrane. Said pressure can be transmitted via the membrane to the top surface or back side of the wafer in order to effect the material removal during CMP. The wafer carrier head can include one or more rigid support components which provide means for fastening the membrane to its mating components, holding the membrane to its desired shape and dimension, and/or clamping the membrane to provide a sealed volume for sealing and containing the controlled gas pressure. Additionally, any of the apparatus and systems described herein can include a controller (e.g., controller 165, FIG. 2) which can be configured to provide the functionality of the methods described herein, and additional functionality. Furthermore, reference numeral 170 illustrates the relative location of a complete CMP apparatus (not shown) which would apply downward force to the wafer 150 attached to wafer carrier head 150 in polishing the wafer against a polishing pad fixed to a rotating platen. For example, the CMP apparatus would apply a downward force to a wafer carrier against polishing pad 110 to polish a wafer 155 when the wafer carrier is configured in a lowered position as shown in FIG. 1. Additionally, wafer carrier head 150 may comprise a membrane attached to the remaining body of the wafer carrier head 150. The membrane (not shown) can be configured to provide pressure between the wafer 155 and the polishing pad 110.

In addition, the CMP system, including the wafer carrier, the polishing platen, and/or the slurry distribution system, may be configured to be controlled by a control system (e.g., the controller 165 of FIG. 2). The control system may be configured to receive feedback from the CMP system and provide control signals to the CMP system. For example, the control system may be configured to provide variable distribution or variable speed functionality for the various components based on feedback signals received from the system.

Systems and Methods for In-Situ Measurement of Material Removal and/or Film Thickness

CMP processes may employ various methods for monitoring material removal and/or film/layer thickness in-situ. Typically, these processes use an average of many measurements, or rely on a single measurement that represents the condition of the entire wafer 155 surface. Due to the use of an average or single measurement, such techniques may not accurately represent the current state of the wafer 155 surface, for example, due to the presence of variations (e.g., peaks and valleys) in the wafer 155 surface.

Aspects of this disclosure relate to system and methods which can use a single or specified number of measurement values, at specified or algorithmically-determined locations, in order to address certain workpiece types, or characteristics, and to provide improved measurement accuracy and higher signal-to-noise ratios.

As is described in detail below, the controller 165 may take multiple measurements and integrate the measurements to determine an average value per scan of the wafer 155 surface area seen by the detector 136 (e.g., ISRM optics). In certain applications, such as wafers 155 having a film with a wide range of film thickness across the wafer 155, the signal generated by the detector 136 may be too noisy to effectively measure the real-time thickness of the film with sufficient accuracy.

Another type of process monitoring uses the measured current of one or more motors to detect changes in friction between the polishing pad 110 and wafer 155 surface, as an indication of changes in the wafer 155 surface during polishing. The amount of friction between the polishing pad 110 and wafer 155 can change and be detected, for example, after a tungsten film has been removed sufficiently to expose an underlying oxide film. While this method uses single measurement points, each measurement point reflects an average or aggregate of conditions on the entire wafer surface, and not individual, known locations.

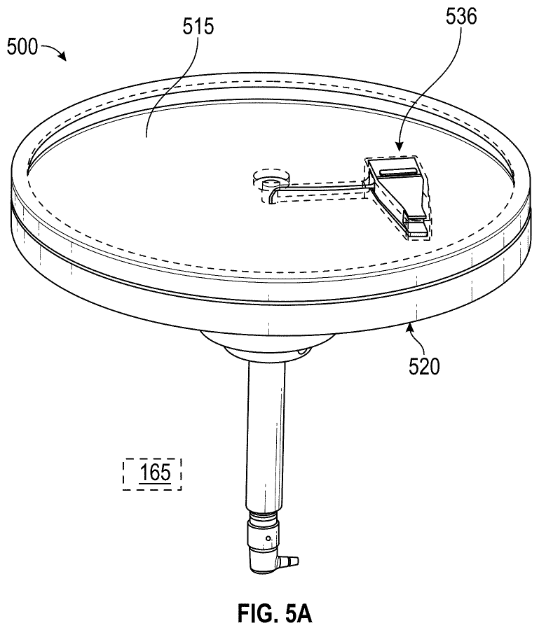

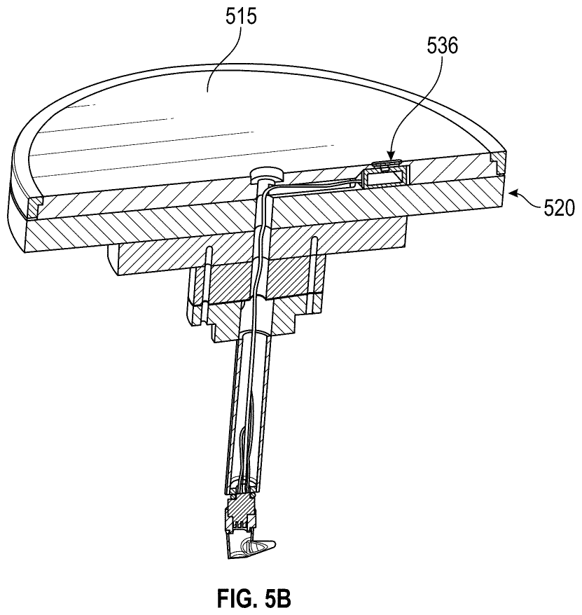

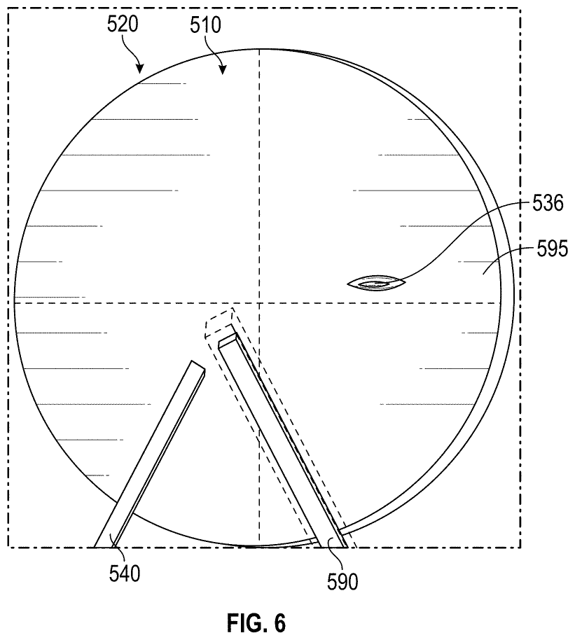

FIGS. 5A and 5B are schematic illustrations of a chemical mechanical planarization system 500 with a detector, e.g., an ISRM optical detector 536 positioned on and/or embedded within another component of the system 500. For example, the optical detector 536 can be embedded within a platen 520, to allow monitoring and detection of a wafer morphology through an opening in an upper surface 515 of the platen 520, and a polishing pad (see FIG. 6), when a wafer is placed on the platen and processed, as described with respect to FIGS. 1-4. A controller, such as the controller 165 of FIG. 2, can use the signals received from the optical detector 536 to measure the removal rate and/or film thickness in-situ.

FIG. 6 is an illustration of the system 500 of FIGS. 5A and 5B, with a polishing pad 510 shown on top of the surface 515 of the platen 520. The system 500 can also include a slurry supply 540 to provide slurry to the process, and a high pressure rinse device 590 to rinse the slurry. The polishing pad 510 can include an opening, and/or a portion with greater transparency than the remainder of the pad 510, to allow transmission of a signal (e.g., an optical signal) to and from the detector 536. For example, a window 595 can allow light from the optical detector 536 to pass through the polishing pad 510. The polishing pad can comprise any of a number of different materials, such as porous polymeric materials, a durable rough layer (e.g., Rodel IC-1000), and/or a fixed-abrasive pad with abrasive particles held in a containment media. The window 595 can comprise a different material than the polishing pad, such as a material with greater transparency relative to that of the polishing pad and negligible diffusing capabilities, to allow for optical transmission through the window, such as silicone or a fluoropolymer, such as poly(pentadecafluorooctylacrylate), poly (tetrafluoroethylene), poly (undecafluororexylacrylate), poly (nonafluropentylacrylate), poly(hepta-fluorobutylacrylate), or poly(trifluorovinylacetate). Additional details regarding the construction and materials used in the polishing pad 510 and the window 595 are provided in U.S. Pat. No. 6,716,085, issued Apr. 6, 2004, which is hereby incorporated by reference in its entirety.

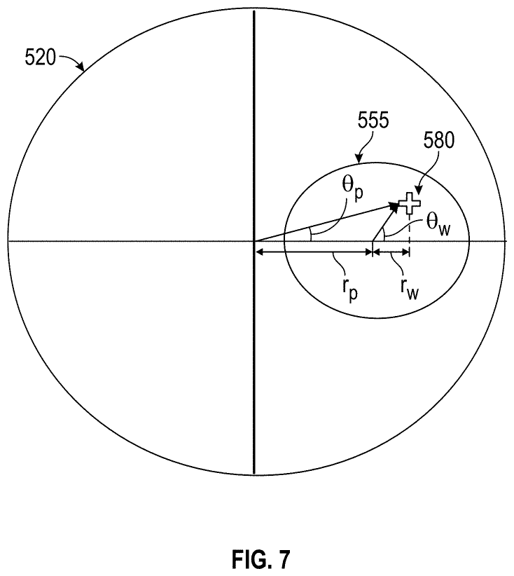

FIG. 7 is a schematic illustrations of a measurement point 580 on a wafer 555, held within a carrier during processing with respect to a platen 520 in accordance with aspects of this disclosure. By tracking the measurement point 580 as the CMP process is performed, the controller 165 can take successive measurements at the same measurement point 580, thereby improving the quality and accuracy of removal rate and/or film thickness measurement. In other words, by measuring specific site(s) 580 on the wafer 555, and then analyzing the measurement(s) to make determinations from that data, the quality and accuracy of the calculations used for monitoring the material removal and/or remaining thickness during CMP processing can be improved.

With reference to FIG. 7, the polish platen 520, the wafer 555, and a measurement point 580 are shown. The wafer 555 is shown in a position where it would be held during processing by a wafer carrier, as discussed and shown elsewhere herein. In the illustration of FIG. 7, the measurement point 580 may be positioned directly above an optical detector, such as the optical detector 536 of FIGS. 5A, 5B, and 6. Also shown are the values: Θp the theta angle between the platen 520 and the measurement site 580 on the wafer 555, Ow the theta angle between carrier and measurement site on wafer, Rp the radial distance between platen and measurement site on wafer, and Θw the radial distance between carrier and measurement site on wafer 555.

In certain implementations, the CMP system can include advanced control systems, in which the exact location of the above listed variables are available to the controller 165 software in real time. For example, embodiments of CMP systems herein can use high-resolution, absolute position encoders connected via a high-speed, deterministic industrial communication network to monitor the positions of all servo axes at intervals as short as 100 microseconds, and produce the above listed variables, or other variables. For instance, the position encoders can be used to determine the relative spatial positions of the carrier (and thus the wafer 555 held by the carrier) with respect to the platen 520 and polishing pad as well as the current angular positions of the wafer and polishing pad. Using the spatial positions and angular positions provided by the position encoders, the system can determine the values illustrated in FIG. 7, and thus, the position of the measurement point 580 on the wafer with respect to the optical detector. This enables the software to calculate a timing regarding exactly when to take a measurement sample, and to know the exact location of said sample on the wafer 555 when the measurement sample is taken. In other implementations, the controller 165 may receive measurements from the optical detector 536 and select those measurements from the stream of data which were taken when the measurement point 580 was positioned above the optical detector 536 to measure the removal rate and/or film thickness at the measurement point 580.

Thus, it is possible for the CMP system to make repeated measurements at specific measurement point(s) 580 on the wafer 555 accurately and consistently, which reduces the variability, or “noise” associated with making more or less random measurements over time, and integrating or averaging those data points to calculate a single data point for analysis. Information determined by such measurements and analysis may be used to control certain aspects of the CMP process. For example, when removing a reflective metal layer over an underlying transparent dielectric layer, the process can be terminated once the required metal removal has been completed. In another example, when removing a prescribed thickness of a homogenous transparent material, the process can be terminated based on the measurement of the thickness, for example, once the prescribed thickness has been reached.

Another aspect of this disclosure is the use of a software algorithm by the controller 165 to take test measurements on multiple locations of the wafer 555, and analyze the data from each site 580 to determine the suitability of using individual sites 580 for repeated measurement. For example, certain sites 580 can be predetermined for measurement and corresponding signal analysis, and them compared to determine the best quality sites 580 for use in subsequent measurements. The system can determine signal quality based on different aspects of the signal samples, such as: amplitude consistency, light spectrum goodness-of-fit (for spectroscopic light source implementations), and others. The controller 165 can then proceed to selectively measure those sites 580 that the controller has determined as providing the best and most useful signal for the remainder of the CMP process.

Another aspect of this disclosure is the ability of the controller 165 to manipulate the motion of the wafer 555 in-situ in order to make measurements at the same location(s) 580 without adversely affecting the CMP process. Typical relative motions during CMP are determined by multiple variables: platen rotation speed, wafer rotation speed, wafer oscillation range, and wafer oscillation frequency. The combination of these variable dictates that the relative position of the measurement sensor may be substantially random for each and every point on the wafer 555. However, in certain aspects the controller 165 can utilizes the hardware and software controls to alter one or more of the above-listed variables on-the-fly, to thereby provide predictive and consistent control the relative position of the optical detector 536 to any site on the wafer 555, without interrupting, disrupting, or otherwise adversely affecting the CMP process.

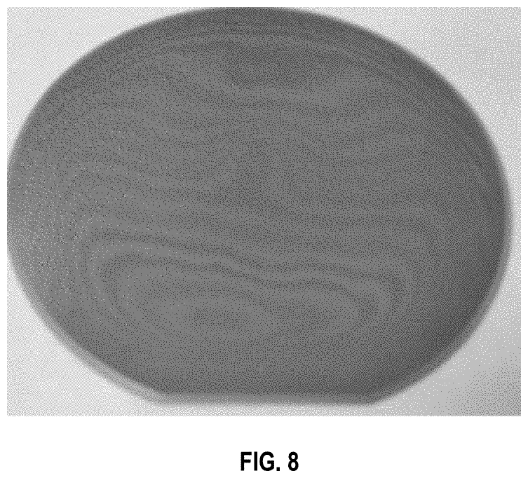

FIG. 8 shows the surface of a wafer with a deposited film with highly-variable thickness across the wafer, evidenced by the different color fringes indicating different film thicknesses. Measurement methods used in traditional systems may involve collecting multiple samples take on essentially random locations on the wafer, and average these together to calculate a data point. Due to the variability of thickness on the wafer, this method is minimally effective for its intended purpose. Aspects of this disclosure represents a substantial improvement by enabling precise and consistent measurement of film thickness at the same location on the wafer during the CMP process.

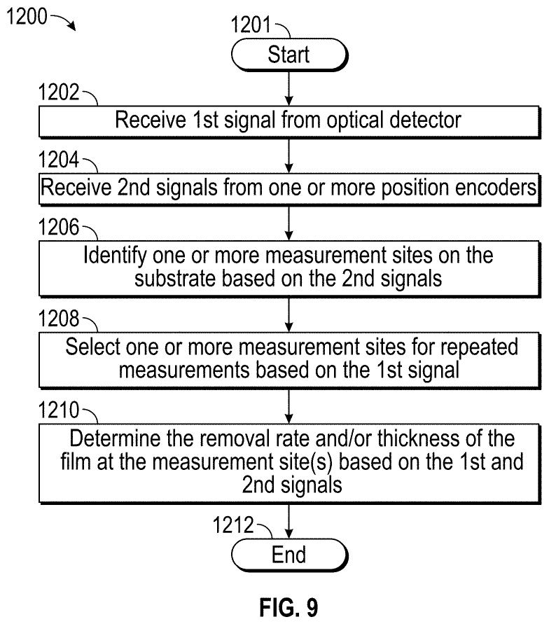

FIG. 9 is a flowchart illustrating a method 1200 for determining a removal rate and/or thickness of a film on a substrate. The method 1200 can implemented, for example, with the apparatus shown and described elsewhere herein, for example, with respect to FIGS. 5A-6.

The method 1200 starts at block 1201. At block 1202, the method 1200 involves receiving a first signal from an optical detector. The detector can be positioned on a side of a polishing pad opposite the substrate. The polishing pad can include an opening extending therethrough.

At block 1204, the method 1200 involves receiving second signals from one or more position encoders. The second signals can be indicative of the spatial and angular positions of a carrier and a platen. The carrier can be configured to retain the substrate and the platen supporting the polishing pad.

At block 1206, the method 1200 involves identifying one or more measurement sites on the substrate based on the second signals.

At block 1208, the method 1200 involves selecting one or more of the measurement sites for repeated measurements based on the first signal.

At block 1210, the method 1200 involves determining the removal rate and/or thickness of the film of the substrate at the selected one or more of the measurement sites based on the first signal and the second signals.

By executing the method 1200, the sensor 300 can provide a more reliable signal to the polisher control system, which can then immediately stop all motion at block 1210 to prevent or minimize damage to the wafer, polishing pad, carrier, etc. based on the signal received from the sensor. By providing a more reliable signal, the methods and systems described herein can prevent the false-detection of a slip due to changes in the polishing conditions which may occur before a steady-state is achieved, which may be a limitation to other traditional techniques.

Additionally, it will be understood that the in-situ monitoring embodiments described herein are not limited to a single-carrier, single-platen system, and can be implemented in other CMP equipment, including multiple-head CMP systems, orbital CMP systems, or other CMP systems.

Many variations and modifications may be made to the above-described embodiments, the elements of which are to be understood as being among other acceptable examples. All such modifications and variations are intended to be included herein within the scope of this disclosure. The foregoing description details certain embodiments. It will be appreciated, however, that no matter how detailed the foregoing appears in text, the systems and methods can be practiced in many ways. As is also stated above, it should be noted that the use of particular terminology when describing certain features or aspects of the systems and methods should not be taken to imply that the terminology is being re-defined herein to be restricted to including any specific characteristics of the features or aspects of the systems and methods with which that terminology is associated.

Conditional language, such as, among others, “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Conjunctive language such as the phrase “at least one of X, Y, and Z,” or “at least one of X, Y, or Z,” unless specifically stated otherwise, is to be understood with the context as used in general to convey that an item, term, etc. may be either X, Y, or Z, or a combination thereof. For example, the term “or” is used in its inclusive sense (and not in its exclusive sense) so that when used, for example, to connect a list of elements, the term “or” means one, some, or all of the elements in the list. Thus, such conjunctive language is not generally intended to imply that certain embodiments require at least one of X, at least one of Y, and at least one of Z to each be present.

The term “a” as used herein should be given an inclusive rather than exclusive interpretation. For example, unless specifically noted, the term “a” should not be understood to mean “exactly one” or “one and only one”; instead, the term “a” means “one or more” or “at least one,” whether used in the claims or elsewhere in the specification and regardless of uses of quantifiers such as “at least one,” “one or more,” or “a plurality” elsewhere in the claims or specification.

The term “comprising” as used herein should be given an inclusive rather than exclusive interpretation. For example, a general-purpose computer comprising one or more processors should not be interpreted as excluding other computer components, and may possibly include such components as memory, input/output devices, and/or network interfaces, among others.

While the above detailed description has shown, described, and pointed out novel features as applied to various embodiments, it may be understood that various omissions, substitutions, and changes in the form and details of the devices or processes illustrated may be made without departing from the spirit of the disclosure. As may be recognized, certain embodiments of the disclosed technology described herein may be embodied within a form that does not provide all of the features and benefits set forth herein, as some features may be used or practiced separately from others. The scope of certain aspects of the technology disclosed herein is indicated by the appended claims rather than by the foregoing description. All changes which come within the meaning and range of equivalency of the claims are to be embraced within their scope.

What is claimed is:

1. A chemical mechanical planarization (CMP) system, comprising:
a carrier configured to retain a substrate;
a platen supporting a polishing pad, wherein the polishing pad includes an opening extending therethrough;
an optical detector positioned on a side of the polishing pad opposite the substrate, and configured to generate a first signal indicative of a removal rate and/or thickness of a film of the substrate through the opening;
one or more position encoders configured to generate second signals indicative of the spatial and angular positions of the carrier and the platen; and
a controller configured to:
receive the first signal from the optical detector and the second signals from the one or more position encoders,
identify one or more measurement sites on the substrate based on the second signals,
select one or more of the measurement sites for repeated measurements based on the first signal, and
determine the removal rate and/or thickness of the film of the substrate at the selected one or more of the measurement sites based on the first signal and the second signals.

2. The system of claim 1, wherein the controller is further configured to determine one or more of the following variables based on the second signals: a first angle between the platen and the selected one or more measurement sites on the substrate, a second angle between the carrier and the selected one or more measurement sites on the substrate, a first radial distance between the platen and the selected one or more measurement sites on the substrate, and a second radial distance between the carrier and the selected one or more measurement sites on the substrate.

3. The system of claim 1, wherein the controller is further configured to:
determine a position of each of the selected one or more measurement sites on the substrate with respect to a position of the optical detector.

4. The system of claim 3, wherein the controller is further configured to:
determine a timing at which to obtain a sample of the first signal for each of the selected one or more position encoders.

5. The system of claim 3, wherein the controller is further configured to:
determine a timing at which to select a measurement from a stream of measurements in the first signal for each of the selected one or more position encoders.

6. The system of claim 1, wherein the controller is further configured to:
obtain a plurality of measurements for each of the selected one or more of the measurement sites based on the first signal and the second signals,
wherein determining the removal rate and/or thickness of the film of the substrate is further based on the plurality of measurements for each of the selected one or more of the measurement sites.

7. The system of claim 1, wherein controller is further configured to:
determine a suitability of using each of the identified one or more measurement sites for repeated measurement,
wherein selecting the one or more of the measurement sites for repeated measurements is further based on the determined suitability.

8. The system of claim 1, wherein the controller is further configured to:
obtain a set of predetermined measurement sites,
compare a signal quality of the first signals corresponding to the predetermined measurement sites, wherein selecting the one or more of the measurement sites is further based on the signal qualities.

9. The system of claim 8, wherein the controller is further configured to determine the signal quality of the first signals based on amplitude consistency and/or light spectrum goodness-of-fit.

10. The system of claim 1, wherein the polishing pad further comprises a window located in the opening and configured to allow light to pass between the optical detector and the substrate.

11. The system of claim 1, wherein the optical detector comprises an in-situ rate monitor (ISRM) optical detector.

12. The system of claim 1, wherein the optical detector is embedded within the platen.

13. The system of claim 12, wherein the platen has an upper surface with an opening formed therein, the opening in the platen overlapping the opening in the polishing pad, and wherein the optical detector is configured to view the substrate via the openings in the platen and the polishing pad.

14. A method for determining a removal rate and/or thickness of a film on a substrate, comprising:
receiving a first signal from an optical detector positioned on a side of a polishing pad opposite the substrate, wherein the polishing pad includes an opening extending therethrough;
receiving second signals from one or more position encoders, the second signals being indicative of the spatial and angular positions of a carrier and a platen, the carrier configured to retain the substrate and the platen supporting the polishing pad;
identifying one or more measurement sites on the substrate based on the second signals;
selecting one or more of the measurement sites for repeated measurements based on the first signal; and
determining the removal rate and/or thickness of the film of the substrate at the selected one or more of the measurement sites based on the first signal and the second signals.

15. The method of claim 14, further comprising:
determining a position of each of the selected one or more measurement sites on the substrate with respect to a position of the optical detector.

16. The method of claim 15, further comprising:
determining a timing at which to obtain a sample of the first signal for each of the selected one or more position encoders.

17. The method of claim 15, further comprising:
determining a timing at which to select a measurement from a stream of measurements in the first signal for each of the selected one or more position encoders.

18. The method of claim 14, further comprising:
obtaining a plurality of measurements for each of the selected one or more of the measurement sites based on the first signal and the second signals,
wherein determining the removal rate and/or thickness of the film of the substrate is further based on the plurality of measurements for each of the selected one or more of the measurement sites.

19. A system, comprising:
a carrier configured to retain a substrate;
a platen supporting a polishing pad comprising a window;
an optical detector configured to view a film of the substrate via the window and generate a first signal indicative of a removal rate and/or thickness of the film;
one or more position encoders configured to generate second signals indicative of the spatial and angular positions of the carrier and the platen; and
a controller configured to:
receive the first signal from the optical detector and the second signals from the one or more position encoders,
identify one or more measurement sites for repeated measurements, and
determine the removal rate and/or thickness of the film of the substrate at the one or more of the measurement sites based on the first signal and the second signals.

20. The system of claim 19, wherein controller is further configured to:
obtain a set of predetermined measurement sites,
compare a signal quality of the first signals corresponding to the predetermined measurement sites, wherein selecting the one or more of the measurement sites is further based on the signal qualities.
